(19) United States
(12) Patent Application Publication
(10) Pub. No.: US 2012/0186070 A1
(43) Pub. Date: Jul. 26, 2012

(54) METHOD FOR RETROFITTING A POWER PLANT

(75) Inventors: Luca DALESSANDRO, Zuerich (CH); Daniel TEUFEL, Stetten (CH); Andreas ROESCH, Murg (DE)

(73) Assignee: ALSTOM TECHNOLOGY LTD, Baden (CH)

(21) Appl. No.: 13/356,559

(22) Filed: Jan. 23, 2012

(30) Foreign Application Priority Data
Jan. 26, 2011 (EP) 11152162.1

(51) Int. Cl. H05K 13/00; B23P 6/00

(52) U.S. Cl. 29/592.1

(57) ABSTRACT

A method for retrofitting a power plant includes the steps of: removing the original active part, removing the original non-active part, providing a new active part that is larger than the original active part, and at least partly extends over a zone that was before occupied by the original active part, and at least partly extends over a zone that was before occupied by the original non-active part, and is housed within the foundation.

### RELATED APPLICATION

The present application hereby claims priority under 35 U.S.C. Section 119 to European Patent application number 11152162.1, filed Jan. 26, 2011, the entire contents of which are hereby incorporated by reference.

### FIELD OF INVENTION

The present invention relates to a method for retrofitting a power plant.

### BACKGROUND

Reference to FIG. 1 is hereinafter made. Power plants traditionally have a prime mover or motor which drives a generator; in particular FIG. 1 shows an example of a power plant 1 with a first motor 2 being a gas turbine and a second motor 3 being a steam turbine; both the gas turbine 2 and the steam turbine 3 are connected at opposite sides of a generator 4.

The gas turbine 2 and the steam turbine 3 lie on a basement 5 and the generator 4 is housed within a foundation 6.

The generator 4 includes an active part and a non-active part.

The active part generates the electric power and typically includes a stator with the stator windings and a rotor with the field windings; in the following the active part is referred to with reference number 7.

The non-active part includes auxiliaries needed for the correct operation of the active part 7; for example FIG. 1 shows a gear box 8 for mechanically coupling the gas turbine 2 to the rotor of the generator 4, an exciter 9 for supplying electric power (typically DC electric power) to the field windings, and a cooler 10.

Naturally, other auxiliaries can also be provided or the cited auxiliaries could not be provided or could be provided at a different location according to the needs and the features of the generator. In this respect the non-active part could be a compressor (for directing compressed air into the active part and cool it) and/or a bushing structure.

Typically (for large generators), the foundation 6 includes (FIG. 16) a pit 11 with a concrete foundation basement 12 for the stator and bearings 13 for the rotor of the generator 4.

The basement 12 (in particular the structure and material thereof) and the bearings 13 (in particular the position or mutual distance thereof) must be designed in order to guarantee a safe rotor dynamics and in particular to avoid resonance frequencies for the rotor (typically around 100-120 Hz for generators operating at 50-60 Hz), because they could be very detrimental and could severely limit the generator reliability.

During operation, the gas turbine 2 and steam turbine 3 drive the generator 4 such that it generates electric power; this electric power is then typically fed to an electric grid (not shown).

In order to increase the electric power that is generated, power plants can be retrofitted to be upgraded.

For example the gas turbine 2 and/or the steam turbine 3 can be replaced with motors of larger power. Alternatively, the stator and/or rotor blades of the gas turbine and/or steam turbine can be replaced, or the temperature of the hot gases expanded within the gas turbine can be increased and/or the features of the steam expanded within the steam turbine can be improved (i.e. in the latter cases only an operational upgrade could be carried out).

Thus a number of possibilities exist to increase the mechanical power that the motors provide to the generator to produce electric power; it is clear that together with the motor upgrade (i.e. gas turbine and/or steam turbine upgrade) also an upgrade of the generator is needed, such that the generator is able to cope with the increased mechanical power that is available.

In order to save time and costs, the foundation, with its basement and the bearings (or at least the seats or positions of the bearings when the bearings are replaced), are often reutilized; in addition, the motors (when this is possible or needed) could also be reutilized.

This causes several space constrains, because the new generator must be housed within the original foundation and in a number of cases it must be connected to the existing motors.

For these reasons, generator upgrade is usually achieved by simply rewinding the stator and rotor windings.

It is clear that, with such a generator retrofitting, the achievable increase of mechanical power that the generator is able to convert into electric power is limited.

### SUMMARY

An aspect of the invention is to provide a method for retrofitting a power plant by which a large power upgrade can be achieved, while at the same time complying with the space constrains.

In particular, an aspect of the invention is to indicate a method by which the power plant can be retrofitted to achieve a large power increase, while reutilizing at least its foundation.

This and further aspects are attained according to the invention by providing a method in accordance with the accompanying claims.

### BRIEF DESCRIPTION OF THE DRAWINGS

Further characteristics and advantages of the invention will be more apparent from the description of a preferred but non-exclusive embodiment of the method, illustrated by way of non-limiting example in the accompanying drawings, in which:

FIGS. 1 and 2 schematically show a power plant before retrofitting respectively in a side and top view;

FIG. 3 schematically shows the power plant during retrofitting;

FIGS. 4 and 5 schematically show the power plant after retrofitting respectively in a side and top view;

FIGS. 6 and 7 schematically show a side view and a top view of the generator before retrofitting (dashed line, original generator) together with the generator after retrofitting (solid line, new generator);

FIGS. 8, 9 and 10, 11 respectively show two different embodiments of the method;

FIGS. 12 and 13 show a preferred embodiment of the method;

FIGS. 14 and 15 show another embodiment of the method; and

FIG. 16 shows a foundation for a generator.

### DETAILED DESCRIPTION OF THE PREFERRED EMBODIMENTS

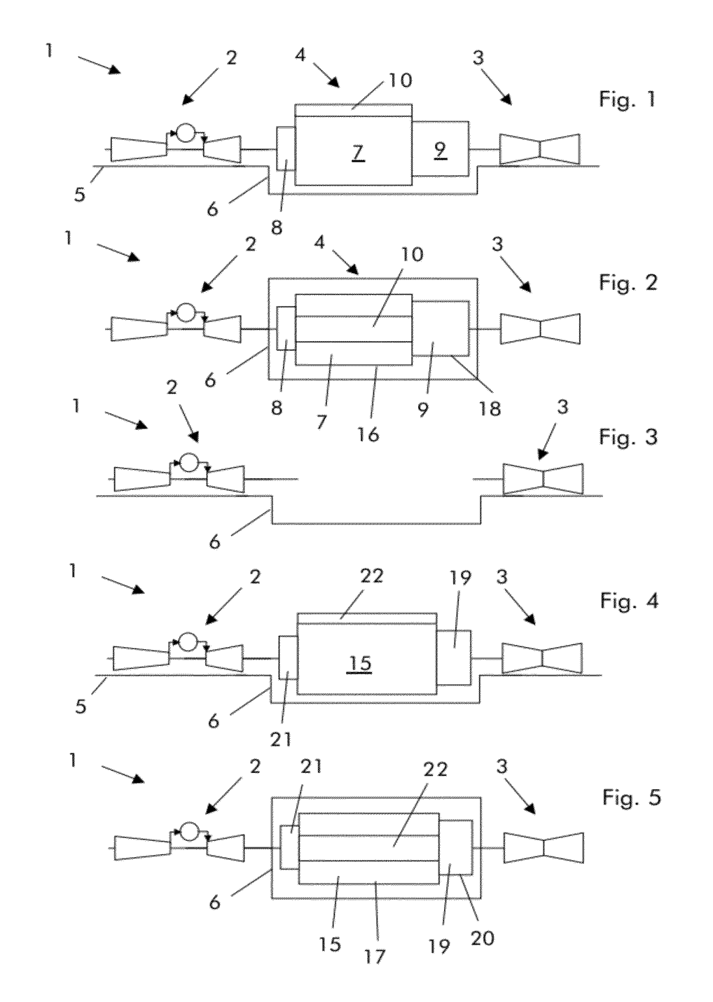

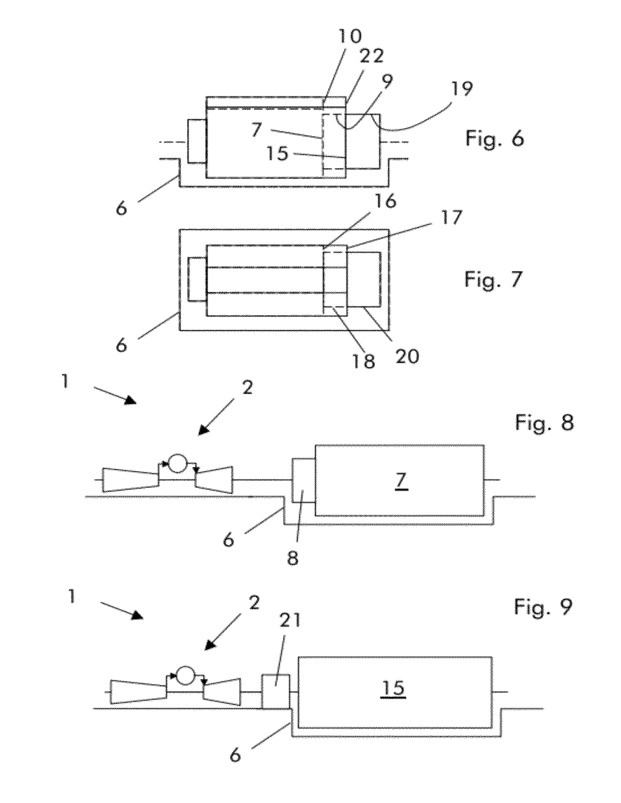

A first embodiment of the method is shown in FIGS. 1 through 7.

In particular FIGS. 1 and 2 show the power plant 1 before retrofitting.

As shown and as already described, the generator 4 comprises the original active part 7 that produces electric power, and the original non-active parts cooperating with the original active part 7.

The original non-active parts include, for example, the gear box 8, the exciter 9 and the cooler 10; in other examples the original non-active part can include a compressor, one or more fans and/or a bushing system. Naturally in further embodiments of the power plant 1 different non-active parts and/or different combinations and/or locations thereof are also possible.

In this example particular reference to the exciter 9 is made, it could be an exciter with slip rings. As shown, the original active part 7 and the original non-active part being the exciter 9 are adjacent to each other.

The active part 7 and the non-active part being the exciter 9 are housed within the foundation 6 that includes the pit 11 with the foundation basement 12 for the stator and the bearings 13 for the rotor of the generator 4.

According to the method, the original active part 7 of the generator 4 is removed.

Thus, the original non-active part being the exciter 9 is also removed (naturally the gear box 8 and cooler 10 are also removed).

FIG. 3 shows an intermediate step of the method with the power plant without the generator 4.

Thus, the method comprises providing a new active part 15 that is larger than the original active part 7.

The new active part 15 extends over a zone that was previously occupied by the original active part 7 and over a zone that was previously occupied by the original non-active part being the exciter 9.

In this respect, FIG. 7 shows the footprint 16 of the original active part 7, the footprint 17 of the new active part 15 and the footprint 18 of the original non-active part being the exciter 9.

Advantageously the new active part is housed within the foundation 6 being the same foundation in which the original active part 7 was housed.

In addition, the bearings 13 are the same as the original bearings or, in case they are replaced, their seats or positions are the same; in other words the mutual distance between the bearings 13 does not change, hence the dynamic behavior of the rotor does not significantly change with respect to the original rotor. This ensures that the resonance frequencies of the new rotor are similar to those of the original rotor and, in any case, far apart from those of the foundation 6. This allows a reliable operation of the new generator without the need of re-designing the foundation 6. Thus, a new non-active part is provided (in particular a new exciter 19).

In this example, the new exciter 19 is smaller than the original exciter 9 (it could be a brushless exciter); in this respect FIG. 7 also shows the footprint 20 of the new non-active part being the exciter 19.

The original gear box 8 and the original cooler 10 can also be replaced (references 21 and 22 respectively indicate a new gear box and a new cooler), but in this example their configuration is not changed to make space for the new active part 15.

In this way the active part of the generator is housed within the same foundation before and after retrofitting but the active part after retrofitting (i.e. the active part of the new generator) is larger than the active part before retrofitting (i.e. the original active part); this allows the generator after retrofitting to generate a larger electric power and to be able to cope with an increased mechanical power from the motors than before retrofitting.

FIGS. 8-9 show a different embodiment of the method; in this example the same numbers indicate the same or similar elements to those already described.

In particular FIG. 8 shows the power plant 1 before retrofitting; in this case the power plant has one single motor being the gas turbine 2 and the original non-active part whose configuration is changed to make space for the larger new active part 15 is the gear box 8; in particular FIG. 8 shows a gear box 8 within the foundation 6.

FIG. 9 shows the power plant of FIG. 8 after retrofitting with the new active part 15 housed within the foundation 6 and a new gear box 21 housed outside of the foundation 6.

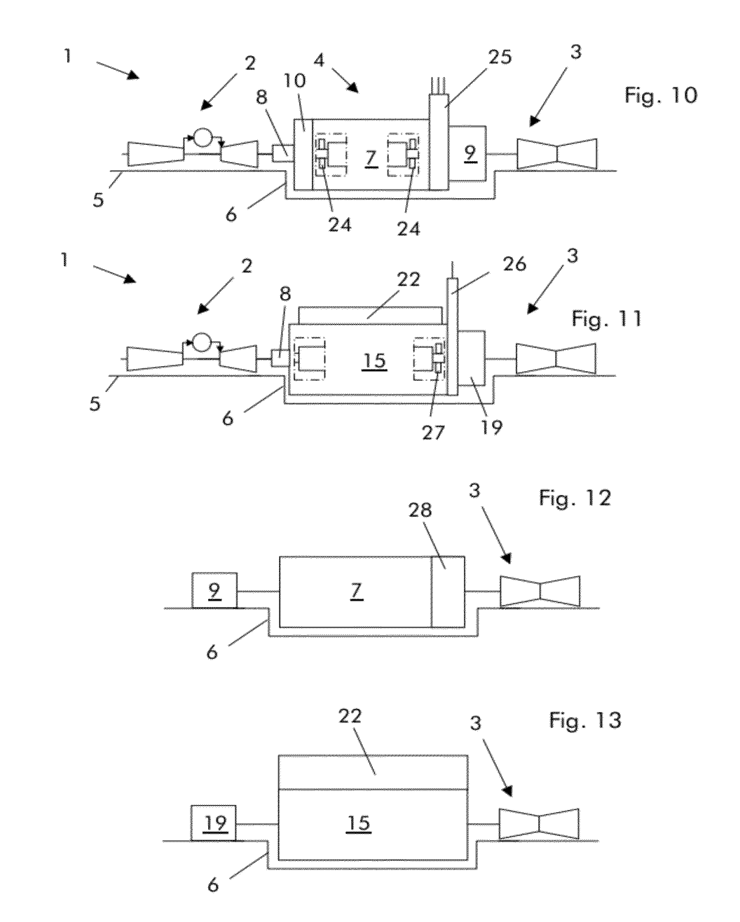

FIGS. 10 and 11 show a further example of the method; also in this example the same numbers indicate the same or similar elements to those already described.

In particular, in this example the dimensions and/or position of more than one non-active parts have been changed to increase the space available for the active part.

FIG. 10 shows the power plant 1 before retrofitting with the active part 7 and the non-active parts that include: a vertical cooler 10, an exciter 9, two cooling fans 24 (one at each axial side of the rotor) and a bushing system 25 (to supply the electric power generated by the generator outside of the generator casing).

FIG. 11 shows the power plant 1 after retrofitting.

The new active part 15 and the new non-active part being the new cooler 22 are overlapped; in particular the new cooler 22 (horizontal cooler) is arranged above the new active part 15.

In addition, a new bushing system 26 and a new exciter 19 have been provided; they are shorter than the original bushing system 25 and exciter 9.

Moreover, the two original fans 24 of the generator shown in FIG. 10 have been replaced with one single fan 27; i.e. one of the fans 24 has been replaced with one fan 27 and the other fan 24 has not been replaced.

The examples above show that the original active part 7 and the original non-active parts (such as the gear box 8, exciter 9, cooler 10, fan 24, bushing system 25) are preferably axially linked.

In this case the new larger active part 15 is axially longer than the original active part 7.

When the new non-active part is smaller than the original non-active part, the new non-active part can be axially shorter than the original non-active part (as shown for the exciter in FIGS. 1-7 and the exciter and bushing system in FIGS. 10-11).

When the new active part 15 and the new non-active part are overlapped, the new non-active part is preferably arranged above the new active part 15 (such as the cooler in FIGS. 10-11).

FIGS. 12 and 13 show a preferred embodiment of the invention; also in this embodiment the same numbers indicate the same or similar elements to those already described.

In this embodiment the original generator (FIG. 12) has an active part 7 with a compressor 28 (or fan) that urges compressed air within the active part 7 to cool it. The active part 7 is connected to a steam turbine 3 and an exciter 9. As shown, the active part 7 and the compressor 28 are housed within the foundation 6, but the exciter 9 and the steam turbine 3 lie outside of the foundation 6.

FIG. 13 shows the generator after retrofitting.

In this case the original active part 7 has been replaced with a new, larger active part 15 and the original compressor 28 has been replaced with a cooler such as for example a horizontal cooler 22 that is connected above the new active part 15.

Thus in this example the original non-active part being the compressor 28 has been replaced with a different non-active part being the cooler 22 having the same cooling function.

The original exciter 9 may be replaced or not and, in any case, it lies outside of the foundation 6. Likewise, also the steam turbine 3 can be replaced or not and it lies outside of the foundation 6.

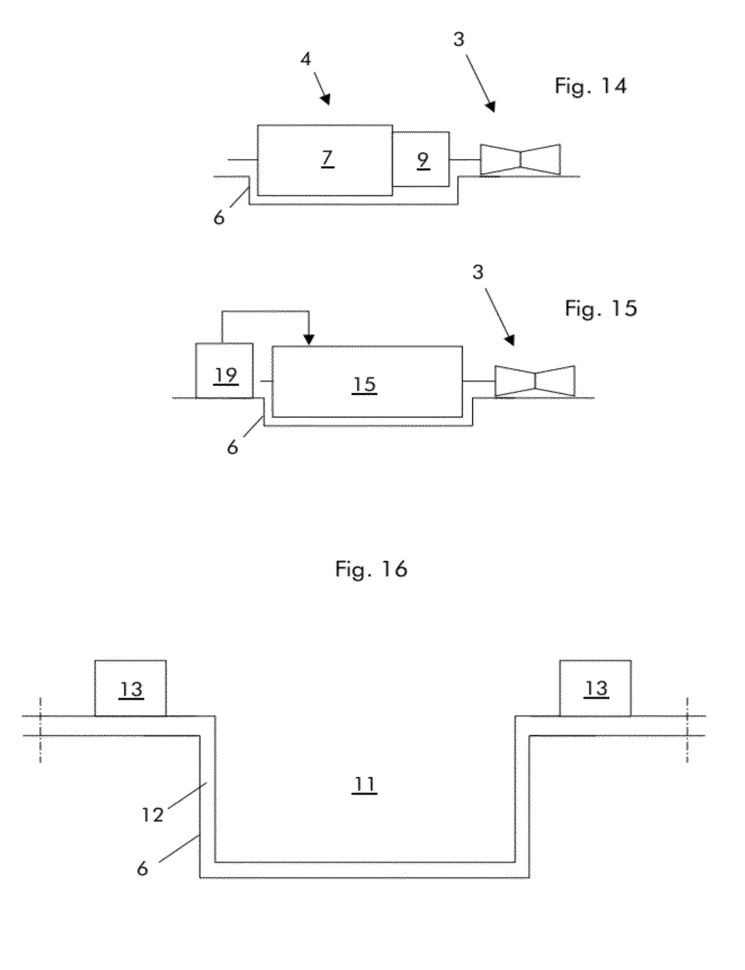

FIGS. 14 and 15 show a further embodiment of the method; also in this embodiment the same numbers indicate the same or similar elements to those already described.

In particular, FIG. 14 shows an example of a generator 4 before retrofitting with the original active part 7 and the original non-active part (exciter 9) housed within the foundation 6.

FIG. 15 shows the generator after retrofitting, with the new active part 15 housed within the foundation 6 and the new non-active part (new exciter 19) that lies outside of the foundation 6.

Upgrade of the motor can be achieved by improving the motor operation, for example increasing the temperature of the hot gases circulating within the gas turbine or improving the features of the steam circulating within the steam turbine.

Alternatively components of the motor can be replaced, for example the stator and/or rotor blades of the gas turbine and/or steam turbine can be replaced and/or the stator and/or rotor blades of the gas turbine compressor can be replaced.

In any event, in a preferred embodiment, upgrading the motor is achieved by replacing it (i.e. the whole motor is replaced).

Retrofitting the power plant according to this method proved to be very time and cost effective, because the foundation can be reused or (if not reused) need not be re-designed.

Naturally the features described may be independently provided from one another.

In practice the materials used and the dimensions can be chosen at will according to requirements and to the state of the art.

### REFERENCE NUMBERS

1 power plant
2 gas turbine
3 steam turbine
4 generator
5 basement
6 foundation
7 active part
8 gear box
9 exciter
10 cooler
11 pit
12 foundation basement
13 bearings
15 new active part
16 footprint of 7
17 footprint of 15
18 footprint of 9
19 new exciter
20 footprint of 19
21 new gearbox
22 new cooler
24 fan
25 original bushing system
26 new bushing system
27 new fan
28 compressor

What is claimed is:

1. Method for retrofitting a power plant (1) comprising a generator (4) connected to at least one motor (2, 3), the generator (4) comprising:
an original active part (7) to produce electric power, and
an original non-active part (8, 9, 10, 24, 25, 28) cooperating with the original active part (7),
a foundation (6) in which the original active part (7) and the original non-active part (8, 9, 10, 24, 25, 28) are housed,
the method comprising the steps of:
removing the original active part (7),
removing the original non-active part (8, 9, 10, 24, 25, 28),
providing a new active part (15), which:
is larger than the original active part (7), and
at least partly extends over a zone that was before occupied by the original active part (7), and
at least partly extends over a zone that was before occupied by the original non-active part (8, 9, 10, 24, 25, 28), and
is housed within the foundation (6).

2. The method according to claim 1, further comprising providing a new non-active part (19, 21, 22, 26, 27) replacing the original non-active part (8, 9, 10, 24, 25, 28), wherein the new non-active part (19, 21, 22, 26, 27) is smaller than the original non-active part (8, 9, 10, 24, 25, 28).

3. The method according to claim 1, further comprising providing a new non-active part (19, 21, 22, 26, 27) replacing the original non-active part (8, 9, 10, 24, 25, 28), wherein the new active part (15) and the new non-active part (19, 21, 22, 26, 27) are at least partially overlapped.

4. The method according to claim 1, further comprising providing a new non-active part (19, 21, 22, 26, 27) replacing the original non-active part (8, 9, 10, 24, 25, 28), wherein the new non-active part (19, 21, 22, 26, 27) is at least partly outside of the foundation (6).

5. The method according to claim 1, wherein the original non-active part (8, 9, 10, 24, 25, 28) is not replaced.

6. The method according to claim 1, wherein the original non-active part (8, 9, 10, 24, 25, 28) is adjacent to the original active part (7).

7. The method according to claim 6, wherein the original active part (7) and the original non-active part (8, 9, 10, 24, 25, 28) are axially linked.

8. The method according to claim 1, wherein the new larger active part (15) is axially longer than the original active part (7).

9. The method according to claim 2, wherein the new smaller non-active part (19, 21, 22, 26, 27) is axially shorter than the original non-active part (8, 9, 10, 24, 25, 28).

10. The method according to claim 3, wherein the at least partly overlapped new active part (15) and new non-active part (19, 21, 22, 26, 27) have the new non-active part (19, 21, 22, 26, 27) arranged at least partly above the new active part (15).

11. The method according to claim 2, wherein the new non-active part (19, 21, 22, 26, 27) lies within the foundation (6).

12. The method according to claim 2, wherein the original non-active part (8, 9, 10, 24, 25, 28) and the new non-active part (19, 21, 22, 26, 27) comprise at least one of: a cooler for the active part; an exciter; a gear box; a fan (24); a compressor; or a bushing structure.

13. The method according to claim 2, wherein the original non-active part (8, 9, 10, 24, 25, 28) is replaced with a different new non-active part (19, 21, 22, 26, 27) having the same function.

14. The method according to claim 1, wherein the foundation (6) includes a pit (11) with a foundation basement (12) for a stator and bearings (13) for a rotor of the generator (4).

15. The method according to claim 1, further comprising upgrading the at least one motor (2, 3).
